(19) United States
(12) Patent Application Publication
(10) Pub. No.: US 2026/0253833 A1
(43) Pub. Date: Aug. 27, 2026

(54) Method of Dispositioning and Control of a Semiconductor Manufacturing Process

(71) Applicant: Fractilia, LLC, Austin, TX (US)

(72) Inventors: Chris Mack, Austin, TX (US); Michael E. Adel, Zichron Ya’akov (IL)

(73) Assignee: Fractilia, LLC, Austin, TX (US)

(21) Appl. No.: 19/648,356

(22) Filed: Apr. 15, 2026

Related U.S. Application Data
(63) Continuation of application No. 18/414,942, filed on Jan. 17, 2024.
Application No. 18/414,942 is a continuation-in-part of application No. 18/329,325, filed on Jun. 5, 2023.
Application No. 18/329,325 is a continuation of application No. 17/316,154, filed on May 10, 2021, now Pat. No. 11,670,480.
Application No. 17/316,154 is a continuation of application No. 16/730,393, filed on Dec. 30, 2019, now Pat. No. 11,004,654.
Application No. 16/730,393 is a continuation of application No. 16/218,346, filed on Dec. 12, 2018, now Pat. No. 10,522,322.
Application No. 16/218,346 is a continuation-in-part of application No. 15/892,080, filed on Feb. 8, 2018, now Pat. No. 10,176,966.
(60) Provisional application No. 62/602,152, filed on Apr. 13, 2017.
(60) Provisional application No. 62/678,866, filed on May 31, 2018.
(60) Provisional application No. 62/739,721, filed on Oct. 1, 2018.

(51) Int. Cl. H01J 37/22; G01Q 30/02; G01Q 30/06; G06T 5/70; G06T 7/13; G06T 7/40; G06T 7/42; G06T 7/49; H01J 37/28

(52) U.S. Cl. CPC H01J 37/222; G01Q 30/02; G01Q 30/06; G06T 5/70; G06T 7/13; G06T 7/40; G06T 7/42; G06T 7/49; H01J 37/28; G06T 2207/10061; G06T 2207/30148; H01J 2237/2814; H01J 2237/2817

(57) ABSTRACT

A method for predicting manufacturing variation is disclosed. The method may include measuring corresponding physical characteristics of multiple semiconductor features on multiple wafers produced using a semiconductor manufacturing process, and estimating a mean and a variance using the corresponding physical characteristics. The method may further include predicting manufacturing variation of the semiconductor manufacturing process using the mean and the variance, controlling the semiconductor manufacturing process using the predicted manufacturing variation, or determining a disposition of at least one of the multiple wafers.

### CROSS-REFERENCE TO RELATED APPLICATIONS

This patent application is a continuation-in-part of U.S. application Ser. No. 18/329,325, filed Jun. 5, 2023 and titled “System and Method for Generating and Analyzing Roughness Measurements,” which is a continuation of U.S. application Ser. No. 17/316,154, filed May 10, 2021 and titled “System and Method for Generating and Analyzing Roughness Measurements,” which is a continuation of U.S. application Ser. No. 16/730,393, filed Dec. 30, 2019 and titled “System and Method for Generating and Analyzing Roughness Measurements”, which is a continuation of Ser. No. 16/218,346, filed Dec. 12, 2018 and titled “System and Method for Generating and Analyzing Roughness Measurements” (now U.S. Pat. No. 10,522,322), which is a continuation-in-part of and claims priority to U.S. application Ser. No. 15/892,080 filed Feb. 8, 2018 titled “Edge Detection System” (now U.S. Pat. No. 10,176,966). U.S. application Ser. No. 16/218,346 claims priority to U.S. Provisional Patent Application No. 62/739,721 filed Oct. 1, 2018 titled “System and Method for Generating and Analyzing Roughness Measurements” and U.S. Provisional Patent Application No. 62/678,866 filed May 31, 2018 titled “System and Method for Removing Noise From Roughness Measurements.” U.S. application Ser. No. 15/892,080 claims priority to U.S. Provisional Patent Application Ser. No. 62/602,152, filed Apr. 13, 2017 and titled “Edge Detection System.”

This application claims priority to and benefit of U.S. Provisional Patent Application No. 63/486,880 filed on Feb. 24, 2023, entitled “Method of Dispositioning and Control of a Semiconductor Manufacturing Process,” the entire disclosure of which is hereby incorporated by reference for all purposes. This application also claims priority to and benefit of U.S. Provisional Patent Application No. 63/487,047 filed on Feb. 27, 2023, entitled “Method of Dispositioning and Control of a Semiconductor Manufacturing Process.”

All applications are incorporated by reference herein in their entirety for all purposes as if reproduced in full below.

### TECHNICAL FIELD

This disclosure relates to semiconductor manufacturing and, more particularly, to metrology and inspection for process control and lot dispositioning.

### BACKGROUND

Integrated circuits are manufactured using a semiconductor manufacturing process that employs multi-step photolithographic and physio-chemical processes that gradually creates electronic circuits on a wafer of single-crystal semiconductor material such as silicon. During the manufacturing process, various steps such as thermal oxidation, thin-film deposition, ion implantation, and etching may be employed.

Metrology and inspection during semiconductor manufacturing may serve the purposes of either, or both, feeding back or forward corrections to processing tools to improve the performance of subsequently printed wafers (process control) or making a rework-or-pass decision on the current lot being measured or inspected (lot dispositioning), among other purposes.

### SUMMARY

Various embodiments of a method for predicting manufacturing variation are disclosed. Broadly speaking, a method may include measuring corresponding physical characteristics of a plurality of semiconductor features on a plurality of wafers produced using a semiconductor manufacturing process, and estimating a mean and a variance using the corresponding physical characteristics. The method may further include predicting manufacturing variation of the semiconductor manufacturing process using the mean and the variance, and controlling the semiconductor manufacturing process using the predicted manufacturing variation.

### BRIEF DESCRIPTION OF THE DRAWINGS

The following detailed description makes reference to the accompanying drawings, which are now briefly described.

FIG. 1 is a block diagram of an embodiment of a semiconductor manufacturing system.

FIG. 2 is a block diagram of an embodiment of a measurement unit.

FIG. 3 is a block diagram of an embodiment of an information system.

FIG. 4. is a block diagram of a multiple patterning test case along with associated measured and calculated metrology parameters.

FIG. 5 is a block diagram illustrating variances for the test case of FIG. 4.

FIG. 6 is a graph depicting predicted excursion counts for stochastic and geometric parameters.

FIG. 7 is a graph depicting the sum of predicted excursion counts.

FIG. 8 is a graph depicting the dependence of an Overlay Process Window on stochastic metrology parameters.

FIG. 9 is a graph depicting the dependence of an Overlay Process Window on different stochastic metrology parameters.

FIG. 10 depicts example of Overlay Process Windows.

FIG. 11 depicts a geometric diagram of a hole over a line.

FIG. 12 depicts a geometric diagram of an elliptical contact over a line.

FIG. 13 depicts a geometric solution to determining an area of a contact over the line.

FIG. 14 depicts the results of a stochastic simulation for a number of predicted excursions.

FIG. 15 depicts a geometric solution for determining an area of a device geometry of a line-end over a via.

FIG. 16 depicts failure rate vs overlay y for area threshold η_{f}=0.3 for differing ratios of R_{L} to Rᵥ.

FIG. 17 is a flow diagram depicting an embodiment of a method for controlling a semiconductor manufacturing process.

FIG. 18 is a flow diagram depicting an embodiment of a method for reworking wafers produced by a semiconductor manufacturing process.

### DETAILED DESCRIPTION

An important part of manufacturing a semiconductor device is the positional accuracy of the overlay of one pattern to a previous pattern on the wafer. The overlay error (sometimes just referred to as the “overlay”) is the deviation of the actual pattern position of a patterned layer in the X-direction and the Y-direction compared to its ideal position relative to a previous patterned layer position. If the overlay error for a layer becomes too large, device performance may suffer, or device yield may be reduced. For this reason, overlay errors are frequently measured and carefully controlled in semiconductor manufacturing.

Overlay measurements are generally performed after a photolithography step that forms a pattern layer in resist. These overlay measurements can be used to feed information back to the photolithography tool to better control its positional accuracy for subsequent wafers or lots. The overlay measurements can also be used for wafer or lot dispositioning. If the current measurements indicate a sufficiently large overlay error, the wafer or lot may be reworked, meaning the patterned resist is stripped off the wafer and a new attempt is made to pattern resist with less overlay error.

Several approaches can be taken for lot dispositioning during semiconductor manufacturing. For example, a threshold may be set on the measured mean±3sigma overlay error or using a location-dependent model to calculate the predicted maximum overlay error in each die (or “chip”) on a wafer. The data supplied to such a model may include only scribe-line test structure measurements (generally performed with optical measurement tools), or a combination of these measurements along with in-die measurements from a scanning electron microscope (SEM). Sometimes critical dimension (CD) measurement data is combined with overlay results in order to determine Edge Placement Error (EPE) using a procedure sometimes referred to as “hybrid metrology.”

The embodiments described herein may provide techniques to estimate the means and variances of metrology data of the dimensions and (relative or absolute) positions of semiconductor features. By combining the mean and variance estimates, a prediction of a proportion of manufacturing excursions, or failures, may be determined. Additionally, the combination of the estimated mean and variance data can be employed to disposition a given wafer or lot of wafers, or control, based on the proportion of predicted manufacturing excursions, a lithography, etch, or other process tool to manufacture a device. In some cases, a dispositioning criterion, which can include a subset of stochastic distribution metrics of Critical Dimension (CD) and/or Line Edge Roughness (LER), Linewidth Roughness (LWR) and/or Edge-Edge Correlations and/or Pattern Placement Error (PPE), and/or overlay of semiconductor features combined with traditional measurements of overlay or other metrology data, may be used to improve an Edge Placement Error (EPE) estimate. By employing the estimated means and variances of metrology data, better control may be maintained resulting in fewer mistakes, better device performance and/or yield, and lower overall manufacturing costs.

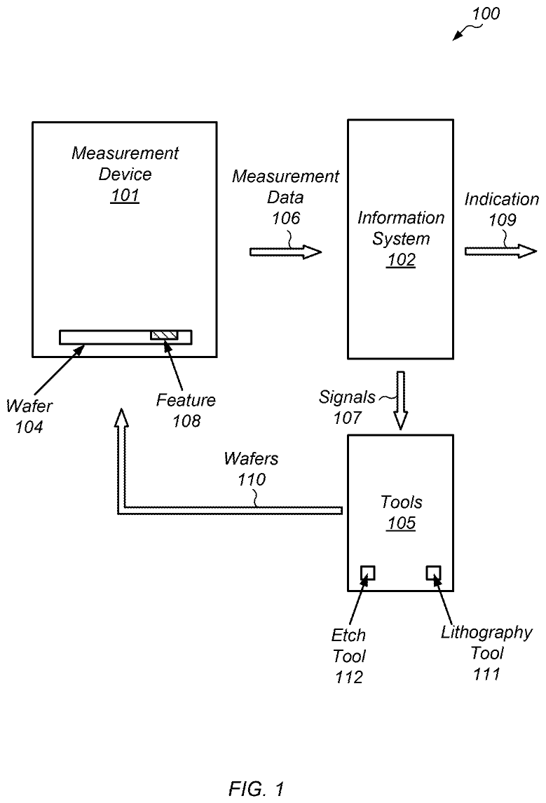

A block diagram of an embodiment of a semiconductor manufacturing system is depicted in FIG. 1. As illustrated, semiconductor manufacturing system 100 includes measurement device 101, information system 102, and tools 105. In various embodiments, semiconductor manufacturing system 100 is used to implement a semiconductor manufacturing process used to fabricate wafers 110. In various embodiments, wafers 110 include multiple integrated circuits.

Measurement device 101 is configured to measure corresponding physical characteristics of feature 108 on wafer 104 to generate measurement data 106. It is noted that although only one feature is depicted in the embodiment of FIG. 1, in other embodiments, any suitable number of features may be employed. Although only a single wafer is depicted in FIG. 1, in other embodiments, measurement device 101 may be configured to measure physical characteristics of multiple features on multiple wafers. In such cases, measurement data 106 may include data from multiple wafers or multiple lots of wafers. Although only one measurement device is depicted in FIG. 1, in other embodiments, multiple measurement devices of different types may be used to measure the same wafer.

Information system 102 is configured to estimate a mean and a variance using measurement data 106, and predict manufacturing variation of the semiconductor manufacturing process using the mean and variance. In various embodiments, information system 102 is further configured to generate, using predicted manufacturing variation, indication 109 which may. include information indicative of a recommendation to rework at least one of wafers or lots 110. In other embodiments, information system 102 may be further configured to, in response to a generation of indication 109, to generate signals 107 for at least one tool of tools 105 used in the semiconductor manufacturing process.

As illustrated, tools 105 may include lithography tool 111 and etch tool 112. In various embodiments, lithography tool 111 may be configured to pattern portions of complex circuit devices and interconnection between devices using photomasks that exposes portions of a light-sensitive polymer (referred to as “photoresist”). In some embodiments, etch tool 112 may be configured to control an etch process during which selected portions of semiconductor processing material (e.g., silicon dioxide) are chemically removed using a plasma or other suitable chemical reaction. Although only two tools are depicted in tools 105, in other embodiments, any suitable number of semiconductor processing tools may be included in tools 105.

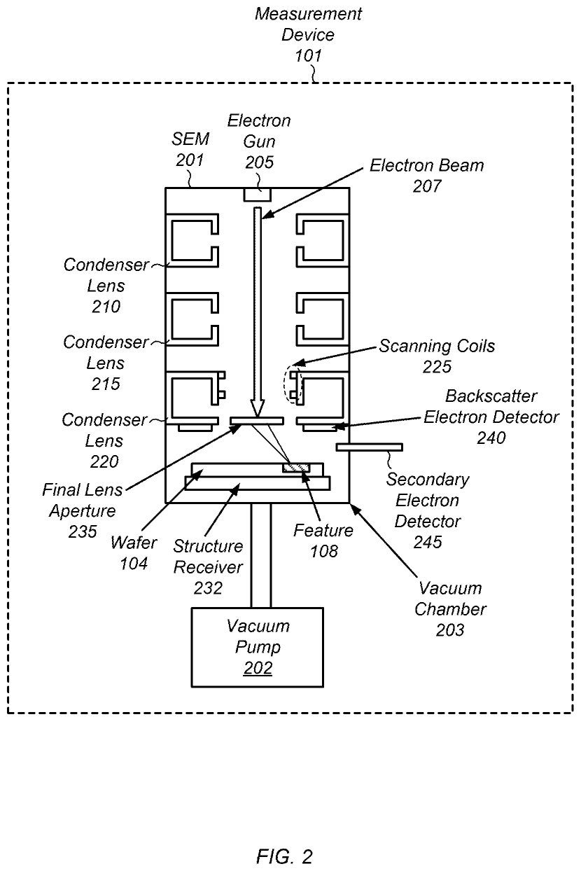

Turning to FIG. 2, a block diagram of measurement device 101 is depicted. As illustrated, measurement device 101 includes scanning electron microscope 201 (denoted as “SEM 201), which includes electron gun 205, condenser lenses 210, 215, and 220, scanning coils 225, and vacuum pump 202. In various embodiments, electron gun 205, condenser lenses 210, 215, and 220, and scanning coils 225 are located within vacuum chamber 203. Vacuum pump 202 may, in different embodiments, be configured to evacuate vacuum chamber 203.

Electron gun 205 is configured to generate electrons to form electron beam 207. In various embodiments, electron gun 205 may be implemented using a heated tungsten filament, a lanthanum hexaboride (“LaB₆”) crystal formed into a thermionic emission gun, or a sharp-tipped metal wire formed to make a field emission gun.

Condenser lenses 210, 215, and 220 are configured to accelerate and focus electrons in electron beam 207. In various embodiments, the energy of the electrons striking wafer feature 108 on wafer 104 may be in the range of 200 eV to 40 keV. In some cases, the energy of the electrons can be in the range of 300 eV to 800 eV for CD-SEMs. For overlay metrology including at least one buried layer, energies higher than 800 eV may be employed. In other cases, measurements using different energies may be combined in order to measure overlay between layers at differing depths.

Condenser lens 220 is configured to employ scanning coils 225 to provide an electric field that deflects electron beam 207 toward wafer 104 as a focused spot. Scanning coils are configured to scan the focused spot across the surface of wafer 104 through final lens aperture 235. In various embodiments, scanning coils 225 may be configured to scan the focused spot in a raster scan fashion to expose a specific field of view on wafer 104.

SEM 201 further includes backscatter electron detector 240 configured to detect backscatter electrons scattering back from wafer 104. SEM 201 also includes a secondary electron detector 246. Prior to imaging, wafer 104 is placed on structure receiver 232 which is configured to support and position wafer 104 within SEM 201. In various embodiments, SEM 201 may also include a controller (not shown) configured to control the raster scanning of wafer 104 during imaging.

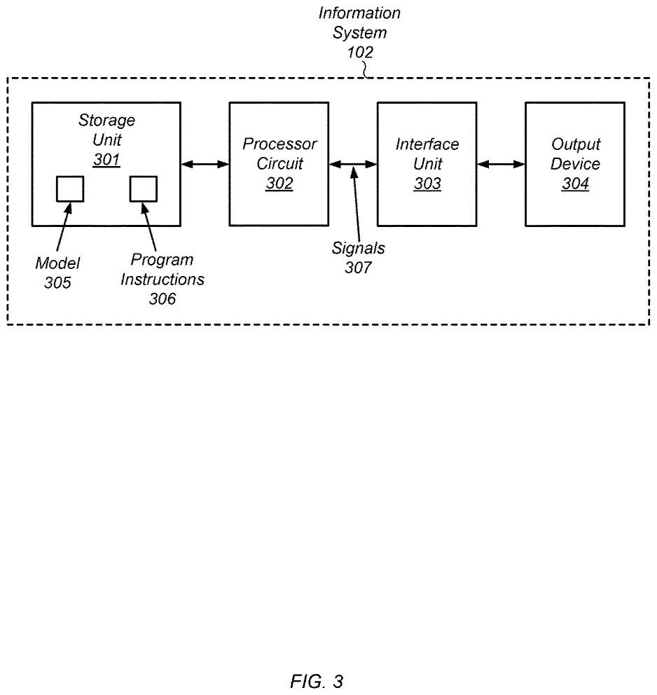

Turning to FIG. 3, a block diagram of information system 102 is depicted. As illustrated, information system 102 includes storage unit 301, processor circuit 302, interface unit 303, and output device 304.

Processor circuit 302 is configured to retrieve program instructions 306 and data associated with model 305 from storage unit 301. In various embodiments, processor circuit 302 is further configured to execute program instructions 306 to generate signals 307, which are used by interface unit 303 to send information to a computer system or to output device 304. In various embodiments, processor circuit 302 may be implemented as a general-purpose processing circuit that performs computational operations. For example, processor circuit 302 may be a central processing unit (“CPU”) such as a microprocessor, a microcontroller, an application-specific integrated circuit (“ASIC”), or a field-programmable gate array (“FPGA”).

Output device 304 may be configured to generate indication 109. In various embodiments, output device 304 may be implemented using a display or monitor, on which indication 109 is displayed. Alternatively, or additionally, output device 304 may include a printer configured to print indication 109 on paper or other suitable medium. Output device 304 may also include a database or other storage media to store indication 109.

A semiconductor manufacturing process may include one or more steps of lithography and etch which when combined form a pattern on the wafer (a patterning process). For example, a “single patterning” processes may begin with the deposition of a layer of material on the wafer. A lithography step may then use a photomask to form a pattern in photoresist on top of this material. A subsequent etching step may transfer that pattern into the material, after which the photoresist is removed. Other patterning processes may involve multiple deposition, lithography, and etch steps to form one pattern on the wafer (called a “multiple patterning” process).

A semiconductor device is created by the application of many patterning steps. In general, one patterning step creates a patterned layer of material on top of a previous pattern of a different material. For example, one patterning step may create holes in an insulating material, while a subsequent patterning step may create metal wires that connect to these holes. A typical semiconductor device may have from a few to dozens or even hundreds of patterning steps to build the many patterned layers required to make the device.

When fabricating a pattern on the wafer, an important property of the pattern is the dimension or dimensions of one or more of the features of the pattern. Such a dimension is called a critical dimension (referred to as a “CD”). It may be a goal of the device fabrication process to control the CD of a feature or features on a pattern to within a tolerance. The control of the CD generally involves the measurement of the CD by a metrology tool.

When fabricating multiple patterns on the wafer, an important property of the patterns is the overlay of one pattern to a previous pattern or patterns on the wafer. The overlay describes the position of one pattern relative to a previous pattern on the wafer. It may be a goal of the device fabrication process to control the overlay of a pattern to a previous pattern to within a tolerance. The control of the overlay generally involves the measurement of the overlay by a metrology tool.

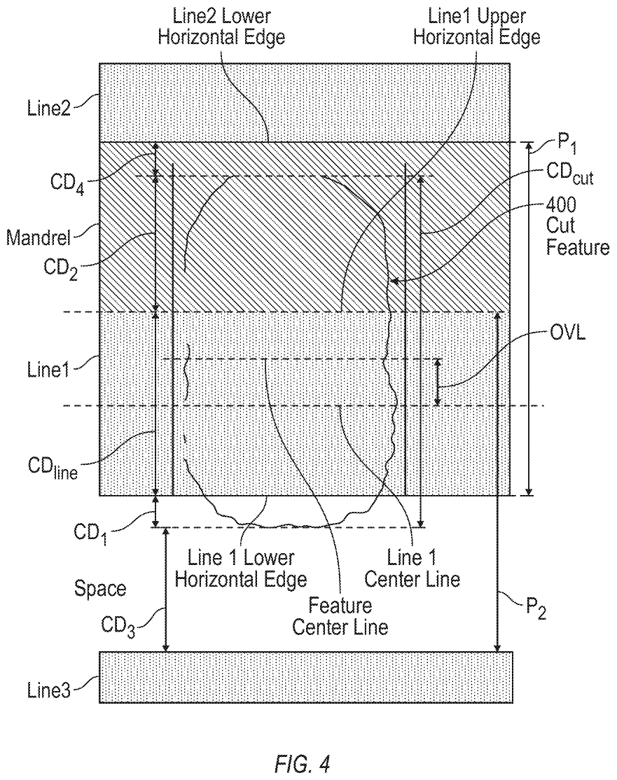

In some cases, a cut mask may be used to cut a line-space pattern, such as a self-aligned double pattern (“SADP”) line-space pattern. For example, an extreme ultraviolet (“EUV”) single patterning cut-mask may be used to cut a self-aligned multiple patterning array of lines and spaces. Critical dimensions (“CDs”) of a resultant feature may be measured using a scanning electron microscope (“SEM”) and the overlay between layers may be measured using an optical overlay measurement tool. A block diagram of such a multiple patterning test case is depicted in FIG. 4. Table 1 depicts four possible failure mechanisms for the embodiment of FIG. 4.

TABLE 1

| | |
|---|---|
| Scenario 1 | CD₁ vanishes, producing an incomplete cut |
| | of the line. |
| Scenario 2 | CD₂ vanishes, producing an incomplete cut |
| | of the line. |
| Scenario 3 | CD₃ vanishes, where the cut reaches the |
| | line below. |
| Scenario 4 | CD₄ vanishes, where the cut reaches the |
| | line above. |

Based on geometric symmetry, scenarios 1 and 2 will behave identically in the model described below. Scenarios 3 and 4 may share a common model, although they may have different input values due to the differences between the pitch/space above and the pitch/space below the cut. Given the similarity between scenarios 1 and 2, and scenarios 3 and 4, the following description is directed to scenarios 1 and 3 with the understanding that scenarios 2 and 4 behave in a similar fashion.

Referring to the geometry depicted in FIG. 4, dimension 1 (denoted “CD₁”) can be expressed by Equation 1, where CD_{cut} is the vertical dimension of the cut feature, CDₗᵢₙₑ is the vertical width of a horizontal line, and OVL is the vertical overlay error between the cut and the line.

$$C {D}_{1} = \frac{C {D}_{cut}}{2} - \frac{C {D}_{line}}{2} - OVL \qquad ( 1 )$$

As noted above, one failure criterion is when CD₁≤0 although, in other embodiments, other criteria relating to CD₁ may be employed. In various embodiments, it can be assumed that CD_{cut}, CDₗᵢₙₑ, and OVL are statistically independent and follow Gaussian distributions with variances σ_{CD}_{_{cut}}, σ_{CD}_{ₗᵢₙₑ}, and σ_{OVL}, respectively. It is noted that while assuming the parameters follow a Gaussian distribution is reasonable, in other cases, other statistical distributions, such as skewed distributions or distributions with greater Kurtosis characterized by other statistical parameters, are possible and contemplated. Under the above assumptions, the variance of dimension 1 can be determined using Equation 2.

$${σ}_{{CD}_{1}}^{2} = \frac{1}{4} ( {σ}_{{CD}_{c u t}}^{2} + {σ}_{{CD}_{l i n e}}^{2} ) + {σ}_{OVL}^{2} . \qquad ( 2 )$$

Equations (1) and (2) can be interpreted as describing the stochastic variations that occur during a patterning process. While FIG. 4 shows one pattern geometry, it is understood that a semiconductor device is made up of thousands, or millions, or billions, or even trillions of such patterns. Ideally, each pattern is identical. It is normal, however, that these patterns vary slightly from each other, for example due to stochastic variations. Under these circumstances, equation (1) can be thought of as describing the mean values of distributions of each variable. Additionally, equation (2) would describe the variances of each variable.

For example, CD_{cut} in equation (1) describes the mean value of a distribution of values for the vertical dimension of the cut feature. It is estimated using the measurement of a sample of cut feature CDs as the mean of the measurement values. In one embodiment, the cut feature CDs are measured using a SEM. Likewise, the variance

$${σ}_{{CD}_{c u t}}^{2}$$

from equation (2) is estimated using the same sample of cut feature CDs.

For scenario 3, a value of dimension 3 (denoted as “CD₃”) can be determined using Equation 3, where CD_{cut}, CDₗᵢₙₑ, and OVL and their variances are defined as above and P₂ is the pitch of the line/space pattern which is equal to the sum: (CDₗᵢₙₑ+CD_{space}).

$$C {D}_{3} = {P}_{2} - \frac{C {D}_{cut}}{2} - \frac{C {D}_{l i n e}}{2} + OVL = {CD}_{s p a c e} - \frac{C {D}_{cut}}{2} + \frac{C {D}_{l i n e}}{2} + OVL \qquad ( 3 )$$

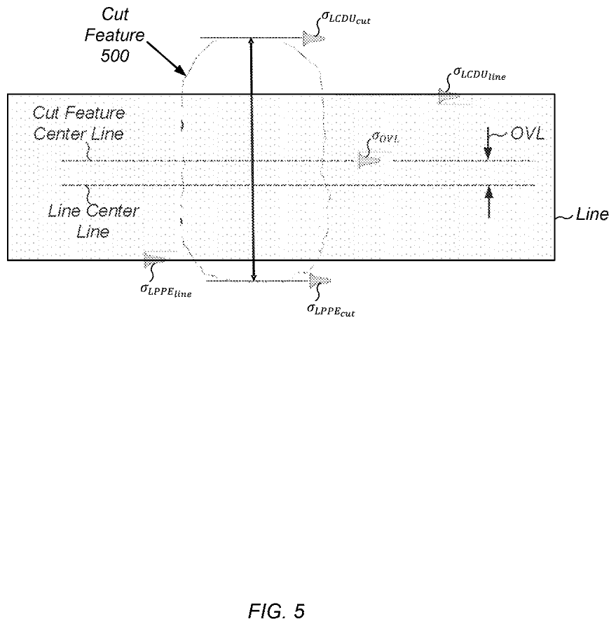

In this case, failures may be investigated by looking for circumstances where CD₃≤0. Under these assumptions, σ_{CD}_{₃}, the variance of the failure mechanism parameter, may be calculated using Equation 4, where the variances, e.g., σ_{OVL}, are illustrated in FIG. 5.

$${σ}_{{CD}_{3}}^{2} = \frac{1}{4} ( {σ}_{{CD}_{c u t}}^{2} + {σ}_{{CD}_{l i n e}}^{2} ) + {σ}_{OVL}^{2} + {σ}_{{CD}_{space}}^{2} = {σ}_{{CD}_{1}}^{2} + {σ}_{{CD}_{space}}^{2} \qquad ( 4 )$$

It is noted that Equation 4 does not take into consideration correlations between CDₗᵢₙₑ and CD_{space}. To account for such correlations, the variance of the failure mechanism can be calculated using Equation 5, where COV (CDₗᵢₙₑ,CD_{space}) is the covariance of the line and space critical dimensions.

$${σ}_{{CD}_{3}}^{2} = \frac{1}{4} ( {σ}_{{CD}_{c u t}}^{2} + {σ}_{{CD}_{l i n e}}^{2} ) + {σ}_{OVL}^{2} + {σ}_{{CD}_{space}}^{2} + COV ( {CD}_{line} , {CD}_{s p a c e} ) \qquad ( 5 )$$

In various embodiments, the covariance can be calculated using Equation 6, where COR(CDₗᵢₙₑ,CD_{space}) is the correlation between CDₗᵢₙₑ and CD_{space}. In the absence of stochastic considerations, the pitch may be assumed constant such that σ_{CD}_{ₗᵢₙₑ}=σ_{CD}_{_{space}}, resulting in COR(CDₗᵢₙₑ,CD_{space})=−1.

$$COV ( {CD}_{line} , {CD}_{s p a c e} ) = {σ}_{{CD}_{line}} {σ}_{{CD}_{space}} COR ( {CD}_{line} , {CD}_{s p a c e} ) \qquad ( 6 )$$

If, however, it is assumed that the left and right edges of both the line and the space can vary independently, then the pitch is not constant over the length scale of interest. In such cases, the line may be considered to be made from two edges e1 and 2, and the space may be made from edges e2 and e3. Using these assumptions, the covariance can be calculated using Equation 7. It is noted that in Equation 7, the covariance is made up of three local edge placement error (“LEPE”) terms, one for each of the three edges, and three correlation terms, indicating how each edge is correlated with the others.

$$COV ( {CD}_{line} , {CD}_{s p a c e} ) = COV ( e 2 - e 1 , e 3 - e 2 ) = COR ( e 2 , e 1 ) {σ}_{{LEPE}_{1}} {σ}_{{LEPE}_{2}} + COR ( e 2 , e 3 ) {σ}_{{LEPE}_{2}} {σ}_{{LEPE}_{3}} - COR ( e 1 , e 3 ) {σ}_{{LEPE}_{1}} {σ}_{{LEPE}_{3}} - {σ}_{{LEPE}_{2}}^{2} \qquad ( 7 )$$

For lines and spaces printed with single patterning, each of the edge correlations may be near zero. Moreover, for uncorrelated edges with identical statistics, it can be assumed that

$${σ}_{{CD}_{space}}^{2} = {σ}_{{CD}_{line}}^{2} = 2 {σ}_{{LEPE}_{2}}^{2} ,$$

which implies that COR(CDₗᵢₙₑ,CD_{space})=−0.5. Accordingly, the covariance can be calculated according to Equation 8.

$$COV ( {CD}_{l i n e} , C {D}_{s p a c e} ) = - 0.5 {σ}_{{CD}_{space}}^{2} \qquad ( 8 )$$

For SADP COR(e1, e3) will be near zero, though this term may be non-zero for SAQP. Also for SADP, COR(e2, e1) (the correlation between the two edges of the line) may be moderately large, whereas COR(e2, e3) may be generally small. In any case, all of these terms are measurable and may be included in a model. For an idealized but extreme SADP case, it can be assumed that σ_{LEPE}_{₁}=σ_{LEPE}_{₂}, COR(e1, e3)=COR(e2, e3)=0, and COR(e2, e1)=1. In this case, COV(CDₗᵢₙₑ,CD_{space})=0. For a still idealized, but more reasonable SADP case, it can be assumed that COR(e2, e1)=0.8. In this case,

$$COV ( {CD}_{l i n e} , C {D}_{s p a c e} ) = - 0.2 {σ}_{{LEPE}_{2}}^{2}$$

Using such assumptions, the covariance may be calculated according to Equation 9.

$$COV ( {CD}_{l i n e} , C {D}_{s p a c e} ) = - 0.1 {σ}_{{CD}_{space}}^{2} \qquad ( 9 )$$

When applying the above-described geometric models, for example, to a wafer or lot rework decision in the fab, inputs to the model are interpreted statistically and supplied by measurements. Further, when stochastic variations are a large (and often dominant) source of the variations of each term, their meaning and measurement can be much less straightforward. For example, the variation of CDₗᵢₙₑ can be broken down into global and local variations as depicted in Equation 10, where global variation is the classical variation wafer-to-wafer, across the wafer, and across the scanner field/slit or die. When interpreting failure rates, however, global variations may be treated as die to die offsets in the mean value of CDₗᵢₙₑ, while within-die variations may be added statistically as @global. Local variations are the result of stochastics.

$${σ}_{{CD}_{line}}^{2} = {σ}_{global}^{2} + {σ}_{local}^{2} \qquad ( 10 )$$

The local CD uniformity (“LCDU”) of the line is not the variation of the CD of the entire line, but the variation of a line segment with a length equal to the nominal cut feature width. In other words, the variation of CDₗᵢₙₑ of concern is the region of overlap between the line and the cut. The LCDU value (σ_{LCDU}_{ₗᵢₙₑ}) can be measured directly using a SEM, but should be unbiased by removing the impact of SEM edge detection noise. Alternately, the LCDU of this short line segment can be modeled based on measurement of the unbiased power spectral density (PSD) of the long line as depicted in Equation 11, where σ_{LWR} is the LWR of the infinitely long line, L is the length of the line segment (that is, the nominal width of the cut feature), ξ is the correlation length of the LWR from the long line (as obtained from its PSD), and H is its roughness exponent. Additional information may be found in U.S. Pat. No. 10,510,509 BB entitled “Edge Detection System,” filed on Dec. 17, 2018, the entire disclosure of which is hereby incorporated by reference for all purposes.

$${σ}_{{LCDU}_{line}} \approx {σ}_{LWR} \sqrt{\frac{( 2 H + 1 ) ξ}{L} ( 1 - \frac{ξ}{L} )} \qquad ( 11 )$$

Similarly, σ_{LCDU}_{_{cut}} has global and local variation components, and the local CDU of the cut in the Y-direction can be measured with a CD-SEM and unbiased (the unbiased measurement should be used in all of the equations presented here). The variation of the pitch (whether P₁ or P₂) has a global component, referred to as “pitch-walking,” caused by global variations in the self-aligned multiple patterning process, and represented in the current case as the global variation in the space width. The local component is the local CDU of the space (σ_{LCDU}_{_{space}}) broken down into the same short segment as used to evaluate σ_{LCDU}_{ₗᵢₙₑ}.

With respect to overlay, there are at least two sources of metrology data which may be used to build estimates of the mean and variance of the distribution. In some cases, it has been demonstrated that pooled overlay data at the wafer level may not be normal in its distribution, displaying both skewness and kurtosis. In some embodiments, the disclosed approach relies on a spatially varying line-to-cut overlay model generated by optical overlay metrology as an estimate of mean overlay which may be varied within the range of the overlay model OVL(x,y) (x and y representing positions within the wafer, field or die). The value of the overlay depicted in Equation 12 can be used to estimate the local variance. In various embodiments, P̅P̅E̅ₗ̅ᵢ̅ₙ̅ₑ̅ and P̅P̅E̅_̅{̅c̅u̅t̅}̅ are the mean pattern placement errors of the line and cut feature respectively, and are typically zero or have a fixed value for a given pattern (the so-called non-zero offset).

$$OVL = OVL ( x , y ) + \overline{{PPE}_{line}} + \overline{{PPE}_{cut}} \qquad ( 12 )$$

The variance can be estimated using Equation 13, where

$${σ}_{Res}^{2}$$

is the variance of the residuals of the overlay model OVL(x,y).

$${σ}_{OVL}^{2} = {σ}_{Res}^{2} + {σ}_{L P P {E}_{c u t}}^{2} + {σ}_{L P P {E}_{l i n e}}^{2} \qquad ( 13 )$$

As previously mentioned, the PPE of both the cut and the line have global (GPPE) and local (LPPE) components. It is noted that Equation 13 relies on an assumption that each of these distributions are statistically independent from one another. This assumption is reasonable since the cut and line features are produced by separate lithographic steps, and the overlay model, while produced by the overlay between those steps, is the result of metrology performed on much larger features in the scribeline.

All sources of variations, both local and global, can be combined to generate an expression of total variances of aforementioned failure parameters as depicted in Equations 14 and 15.

$${σ}_{{CD}_{1}}^{2} = \frac{1}{4} ( {σ}_{{GCDU}_{cut}}^{2} + {σ}_{{LCDU}_{cut}}^{2} + {σ}_{{GCDU}_{line}}^{2} + {σ}_{{LCDU}_{line}}^{2} ) + {σ}_{Res}^{2} + {σ}_{{LPPE}_{cut}}^{2} + {σ}_{{LPPE}_{line}}^{2} \qquad ( 14 )$$

$${σ}_{{CD}_{3}}^{2} = {σ}_{{CD}_{1}}^{2} + {σ}_{{GCDU}_{space}}^{2} + {σ}_{{LCDU}_{space}}^{2} \qquad ( 15 )$$

The CDU terms from Equation 9 can be grouped to generate Equation 16.

$${σ}_{{CDU}_{1}}^{2} = {σ}_{{GCDU}_{cut}}^{2} + {σ}_{{LCDU}_{cut}}^{2} + {σ}_{{GCDU}_{line}}^{2} + {σ}_{{LCDU}_{line}}^{2} \qquad ( 16 )$$

Substituting Equation 16 into Equation 14 yields a simplified equation for

$${σ}_{{CD}_{1}}^{2}$$

as depicted in Equation 17.

$${σ}_{{CD}_{1}}^{2} = \frac{1}{4} {σ}_{{CDU}_{1}}^{2} + {σ}_{OVL}^{2} \qquad ( 17 )$$

It should be appreciated that while the above method specifies a variance equation combining both local and global contributions, other variants, such as including only the local variances, are possible and contemplated.

In some embodiments, a pass/fail criterion may be based on an excursion count relying on a cumulative normal distribution function assuming a Gaussian distribution, which is a fraction of cuts that fail based on the two criteria. The excursion count can be determined using Equation 18, where x₀ is a failure threshold (for the present case, x₀ has been set to zero), u is the nominal (mean) value of either CD₁ or CD₃ as determined by Equation 1 or Equation 3, and 02 is the variance as defined in either of Equations 14 or 15.

$$f ( {x}_{0} , μ , σ ) = \frac{1}{\sqrt{2 π} σ} {\int }_{- ∞}^{{x}_{0}} {e}^{- \frac{{( x - μ )}^{2}}{2 {σ}^{2}} dx} \qquad ( 18 )$$

In the case of a zero threshold value, the function of Equation 18 can be simplified to that depicted in Equation 19.

$$f ( {x}_{0} = 0 , μ , σ ) = \frac{1}{\sqrt{2 π} σ} {\int }_{- ∞}^{{x}_{0}} {e}^{- \frac{{( x - μ )}^{2}}{2 {σ}^{2}} dx} = \frac{1}{2} erfc ( \frac{μ}{\sqrt{2} σ} ) \qquad ( 19 )$$

In general, the fraction of failure can be small, meaning that >>σ. In this case, the complimentary error function, c, can be approximated as shown in Equation 20.

$$f ( {x}_{0} = 0 , μ , σ ) = \frac{1}{2} erfc ( \frac{μ}{\sqrt{2} σ} ) \approx \frac{σ}{\sqrt{2 π} μ} {e}^{- \frac{{μ}^{2}}{2 {σ}^{2}}} \qquad ( 20 )$$

It is noted that the approximation of Equation 20 is off by 2.6% at the 1 part-per-billion (“ppb”) failure rate, and off by 4% at the 1 part-per-million (“ppm”) failure rate. The failure rate is controlled by

$$\frac{σ}{μ} ,$$

with larger values producing greater rates of failure. For example,

$$\frac{σ}{μ} = 0.167$$

produces a 1 ppb failure rate, while

$$\frac{σ}{μ} = 0.210$$

produces a 1 ppm failure rate. It some cases, the failure rate can be expressed on a log-scale as shown in Equation 21. It is noted that when the failure rate is expressed on a log-scale, the failure rate may vary in an approximate quadratic fashion with

$$\frac{μ}{σ} .$$

$$ln ( failure ) \approx ln ( \frac{σ}{\sqrt{2 π} μ} ) - \frac{{μ}^{2}}{2 {σ}^{2}} \qquad ( 21 )$$

For the scenarios 1 and 2 described above, the

$$\frac{σ}{μ}$$

ratio can be defined as shown in Equation 22A and 22B, respectively. It is noted that the only difference between the two equations is the sign of the OVL term.

$$\frac{{σ}_{{CD}_{1}}}{{CD}_{1}} = \frac{\sqrt{\frac{1}{4} {σ}_{{CDU}_{1}}^{2} + {σ}_{OVL}^{2}}}{\frac{1}{2} ( {CD}_{cut} - C {D}_{l i n e} ) - OVL} \qquad ( 22 A )$$

$$\frac{{σ}_{{CD}_{2}}}{{CD}_{2}} = \frac{\sqrt{\frac{1}{4} {σ}_{{CDU}_{1}}^{2} + {σ}_{OVL}^{2}}}{\frac{1}{2} ( {CD}_{cut} - C {D}_{l i n e} ) + OVL} \qquad ( 22 B )$$

Using the equations described above, the excursion count (i.e., the fraction of failed cuts) for a given scenario can be predicted. Table 2 contains a set of geometric and stochastic parameters which can be used as input. Nominal values for the mean CDs may be used, but global variations from die-to-die and wafer-to-wafer may also be used to account for offsets to these nominal values.

TABLE 2

| | Parameter | Parameter |
|---|---|---|
| Parameter name | symbol | value [nm] |
| Line CD | CDₗᵢₙₑ | 14 |
| Space CD | CD_{space} | 14 |
| Mandrel CD (same as Space CD) | CD_{space} | 14 |
| Cut CD | CD_{cut} | 28 |
| Cut extension over space | CD₁ | Calculated using |
| | | Equation 1 |
| Cut extension over mandrel | CD₂ | Calculated using |
| | | Equation 1 using |
| | | opposite overlay sign |
| Overlay (varied) | OVL | −7 to +7 |
| Line global CD uniformity | σ_{GCDU}_{ₗᵢₙₑ} | 0.6 |
| Line local CD uniformity | σ_{LCDU}_{ₗᵢₙₑ} | 0.7 |
| Line local pattern placement error | σ_{LPPE}_{ₗᵢₙₑ} | 0.4 |
| uniformity | | |
| Cut global CD uniformity | σ_{GCDU}_{_{cut}} | 0.8 |
| Cut local CD uniformity | σ_{LCDU}_{_{cut}} | 0.9 |
| Cut local pattern placement error | σ_{LPPE}_{_{cut}} | 0.5 |
| uniformity | | |
| Space global CD uniformity | σ_{GCDU}_{_{space}} | 0.7 |
| Space local CD uniformity | σ_{LCDU}_{_{space}} | 0.7 |
| Overlay (model residuals) | σ_{Res} | 0.8 |
| Overlay (total standard deviation) | σ_{OVL} | Calculated using |
| | | Equation 8 |
| Cut extension over space | σ_{CD1} | Calculated using |
| uniformity | | Equation 9 |
| Cut extension over mandrel | σ_{CD2} | Calculated using |
| uniformity | | Equation 9 |

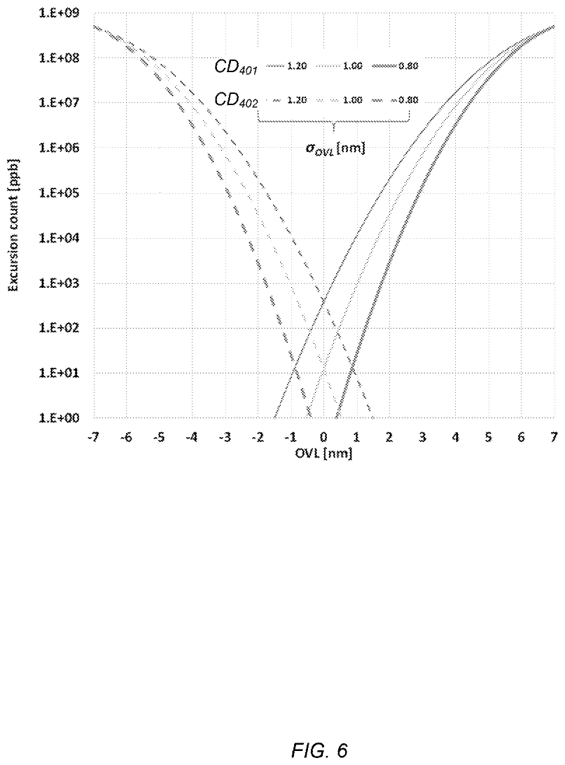

In FIGS. 6-10, the number of excursions have been generated using scenarios 1 and 2 as described above. It is noted that, in various embodiments, the sum of the number of excursions for scenarios 1-4, or any suitable combination of the excursion counts for scenarios 1-4, may be employed, including those not explicitly described in this disclosure.

Turning to FIG. 6, a graph depicting excursion counts for dimensions 1 and 2 is depicted. As illustrated, the excursion counts for dimensions 1 and 2 are plotted as a function of overlay for three different values of σ_{OVL}. As expected, the graphs for CD₁ and CD₂ display reflection symmetry about zero overlay. It is noted that the graphs for CD₃ and CD₄ display similar behavior and have been omitted for clarity.

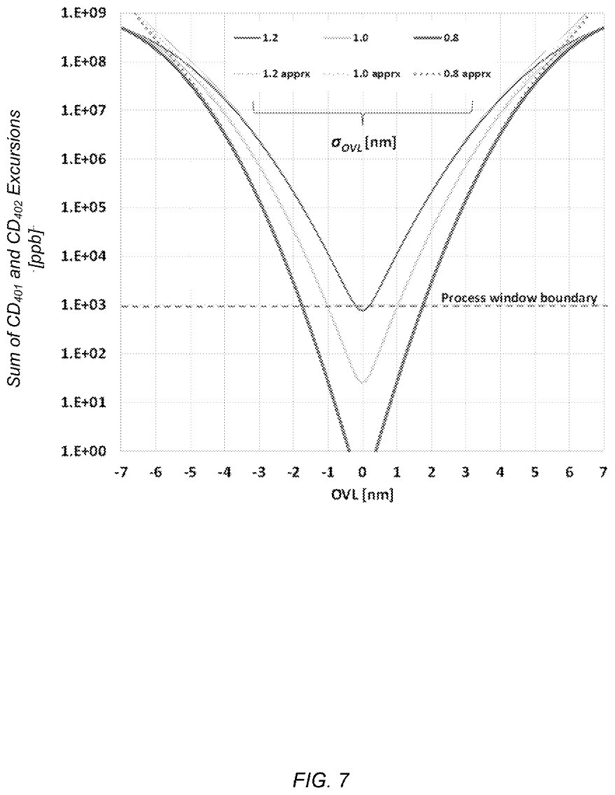

Turning to FIG. 7, an example graph of the sum of the excursion counts for CD₁ and CD₂ as a function of overlay is depicted. Additionally, the results generated using the approximations defined in Equation 20 are also depicted in FIG. 7. In the regime of interest, where overlay is small, the discrepancy between the approximation and the accurate expression of Equation 19 can be negligible. In various embodiments, the approximate expression may be used rather than the accurate expression.

In order to define an Overlay Process Window (OPW), an excursion threshold may be set. By way of example, in FIG. 7 the excursion threshold has been set at 1 failure per million. In other embodiments, the excursion threshold can be calibrated using measured die yield or similar data. FIG. 7 indicates that, depending on the selected values of the stochastic or geometric parameters, the range of the overlay parameter (x axis) for which the excursion count is below the threshold can be determined, which corresponds to the OPW. It is observed in FIG. 7 that the OPW can be visually estimated to be about 3.5, 2, and 0.5 nanometers for the cases of σ_{OVL}=0.8, 1.0, and 1.2 nanometers, respectively. It is noted that increases in the stochastic parameter σ_{OVL} on the order of Angstroms can result in shrinkage of the OPW at the scale of nanometers, indicating that accurate and or precise estimates or measurements of these parameters are important.

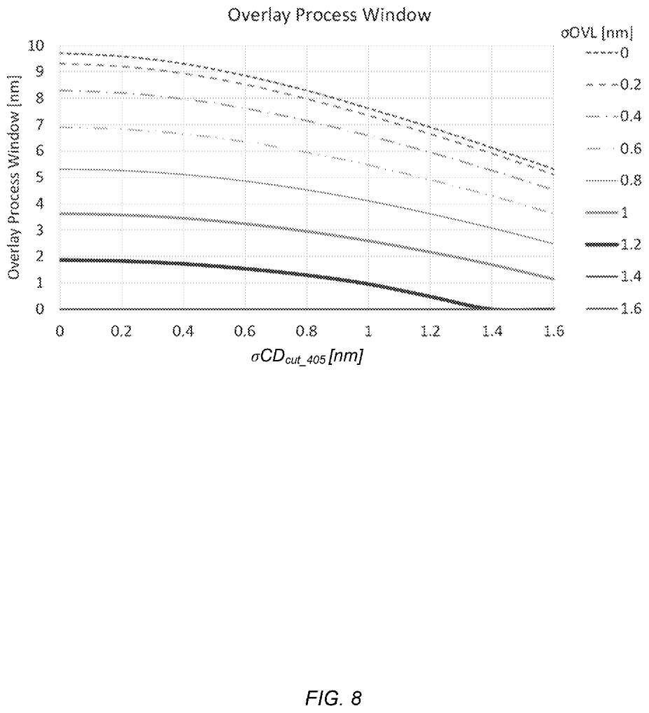

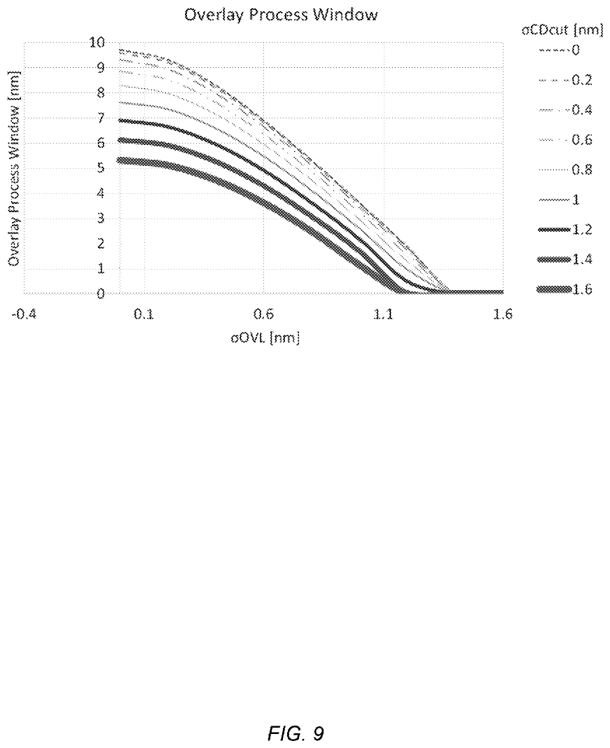

To evaluate the dependence of the OPW on stochastic parameters, an interpolation technique can be employed to determine the 1 ppm crossover point of an excursion count curve versus overlay. An example graph of the OPW as a function of σ_{CD}_{_{cut}} is depicted in FIG. 8, while an example graph of the OPW as a function of σ_{OVL} is depicted in FIG. 9. The graphs illustrated in FIGS. 8 and 9 depict the use of stochastic and/or geometric parameters in order to quantify the OPW.

In comparing the graphs of FIGS. 8 and 9, it is noted that OPW diminishes more rapidly with σ_{OVL} than with σ_{CD}_{_{cut}}. This can be a result of the geometric dependence of CD₁ on OVL, CD_{cut}, and CDₗᵢₙₑ as depicted in Equation 1.

While the above examples display symmetry of the excursion count with respect to OVL, with the center of symmetry centered at nominal zero overlay, there may be, in some embodiments, cases where the function is not symmetric about nominal zero overlay. Such a situation can occur when failures due to CD₃ and CD₄ are also taken into consideration, that is, when the cut feature's position is vertically shifted to the extent that it reached the line above or the line below, i.e., CD₃ and CD₄.

Referring to FIG. 4, it is noted that the top of CD₄ is a mandrel edge, while the bottom of CD₃ is a space edge. Since the stochastic behavior of these two edges differ in general, it can be assumed that they will impact the process window differently. An alternate way to express this is to note that the process window shift is the result of pitch-splitting between P₁ and P₂. As previously described, a simplifying assumption that there is no correlation between the mandrel and space dimensions and edge locations can be made. Moreover, differing EPE statistics, which are due to the differing process steps involved in their creation, along with the previous assumption can be used to generate Equations 23A and 23B.

$${σ}_{{GCDU}_{mandrel}} \neq {σ}_{{GCDU}_{space}} \qquad ( 23 A )$$

$${σ}_{{LCDU}_{mandrel}} \neq {σ}_{{LCDU}_{space}} \qquad ( 23 B )$$

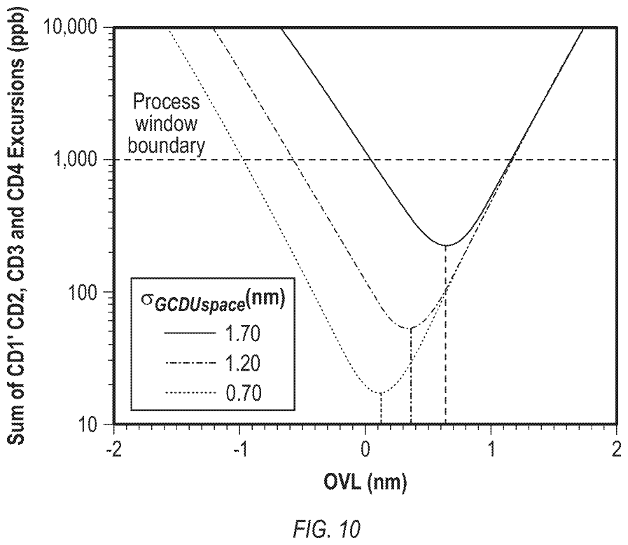

The resultant overlay process windows are displayed in FIG. 10 for three different values of global CD uniformity of the space feature. It is noted that the shapes of the process windows remain symmetric about their axes passing through their minima. Furthermore, not only do the process windows shift upwards, but the location of the minima is shifted from overlay zero away from the edge with greater CD non-uniformity, in this case in the positive direction away from the space. Based on this data, it can be concluded that the lithographic alignment control set point should be biased away from zero by an amount determined by the shift in the overlay process window, i.e., 1.2, 3.3 and 7.4 Angstroms from the nominal geometric alignment location for the cases simulated. In various embodiments, the nominal overlay control point can be biased away from the geometric center of symmetry by an amount that can be calculated based on stochastic variance parameters.

It is further noted that while in the current example the process window was calculated in the parameter space of overlay, this is by no means limiting, and examples may be envisaged in which the process window is in an alternative parameter space such as CD, CD uniformity, or any other geometric or stochastic parameter. Furthermore, by varying multiple parameters and recursively replicating said excursion count estimations, the method may be generalized to define a “process volume” of arbitrarily large dimensionality within which the predicted excursion count remains within tolerable bounds.

It is also instructive to consider more carefully the definition of the process window boundary. As described above, the process window boundary was defined generically in excursion counts, without specifying within which domain. By way of example, the domain within which excursions are counted may be the full wafer, lithographic field, die, specific region within the die, or any other convenient or functional domain definition. In some embodiments, the excursion count per die may be calculated based on different input parameters to the model. For example, a mean of a CD of either a line or a cut feature may be determined by metrology for each die independently. Furthermore, σ_{global} may be determined by metrology for each die independently, allowing a “per die” process window to be calculated. This approach may be applied utilizing metrology data from an optical CD or overlay tool performing metrology on either scribeline or in-die targets. In a further embodiment, the weight attributed to an excursion in one region of a die may be higher than that attributed in another region of a die due to varying levels of fault tolerance across the die.

In a different embodiment of the present disclosure, a visualization can be generated by using process window results calculated on a per die or per field basis to create a wafer map of said process window. In other embodiments, location dependent process window results may be used in order to modify control parameters of a lithographic, etch, or other process tool in a subsequent manufacturing step in order to maintain subsequent process window results within specified performance limits.

It should also be noted that while, in this example, all output parameters were calculated analytically based on either known feature design rules or measured metrology data, it is also possible to estimate the excursion count as a function of input parameters, or determine the OPW using, as described below, a statistical simulation in which a series of randomly varied parameters are used as input.

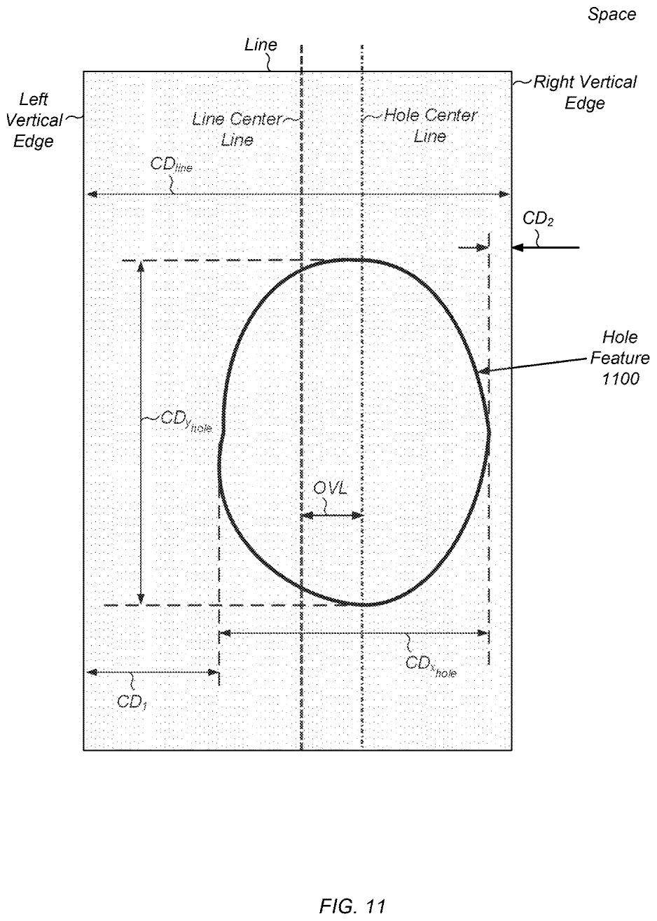

Turning to FIG. 11, a geometric diagram depicting a case of a contact hole landing on a line is illustrated. In this case, CDₗᵢₙₑ>CDₓₕₒₗₑ and the failure of concern is when the hole space CD vanishes. Based on the geometry depicted in FIG. 11, CD₁ and CD₂ can be defined as shown in Equations 24 and 25, respectively.

$${CD}_{1} = \frac{{CD}_{l i n e}}{2} - \frac{{CD}_{x h o l e}}{2} + OVL \qquad ( 24 )$$

$${CD}_{2} = \frac{{CD}_{l i n e}}{2} - \frac{{CD}_{x h o l e}}{2} - OVL \qquad ( 25 )$$

This case is mathematically equivalent to the case for a line pattern cut as described above, however, it may be treated differently from a stochastic perspective. The CD₁ or CD₂ failure is dependent on the stochastic variation of CDₗᵢₙₑ on a length scale substantially smaller than CD_{yhole} and independent of CDₓₕₒₗₑ, i.e., the eccentricity. Accordingly, in various embodiments, a length scale for estimating the stochastic variation of the input parameters of the expressions for CD₁ and CD₂ may be selected in accordance with the length of contact between the hole and the line.

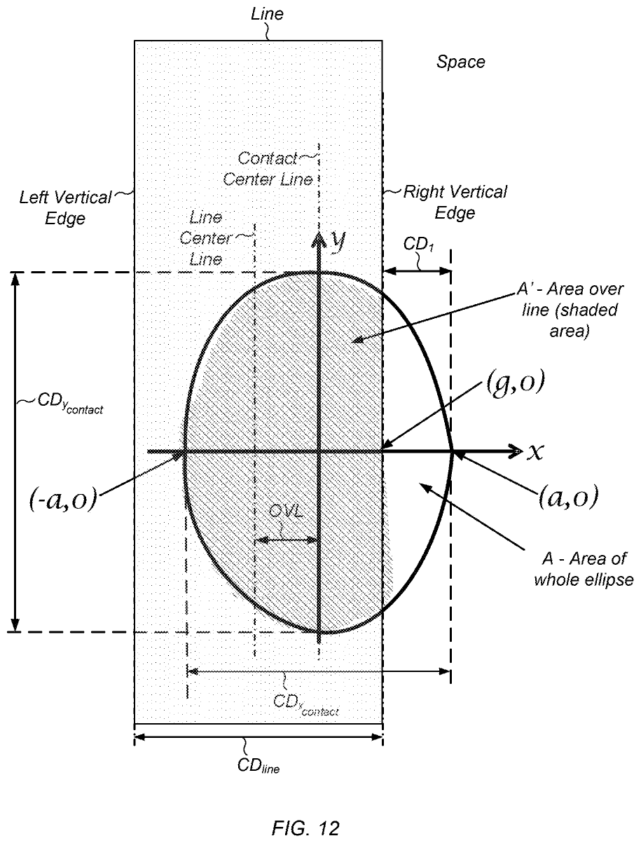

Turning to FIG. 12, a geometric diagram illustrating the case of an elliptical contact over a line is depicted. Overlay zero is defined as a centered contact and is normalized to CDₓ_{_{contact}}. In some embodiments, a failure criterion may be defined by an area A′ of the contact which is over the line. In the first case, the area may be calculated according to Equation 26, where

$$a = \frac{C {D}_{{x}_{contact}}}{2} , b = \frac{C {D}_{{y}_{contact}}}{2} , and g = \frac{C {D}_{{x}_{contact}}}{2} - OVL .$$

$${A}^{′} = {\int }_{- a}^{g} 2 b \sqrt{1 - \frac{{x}^{2}}{{a}^{2}}} dx = ba [ arsin ( \frac{g}{a} ) + \frac{π}{2} + \frac{1}{2} sin ( 2 arcsin ( \frac{g}{a} ) ) ] \qquad ( 26 )$$

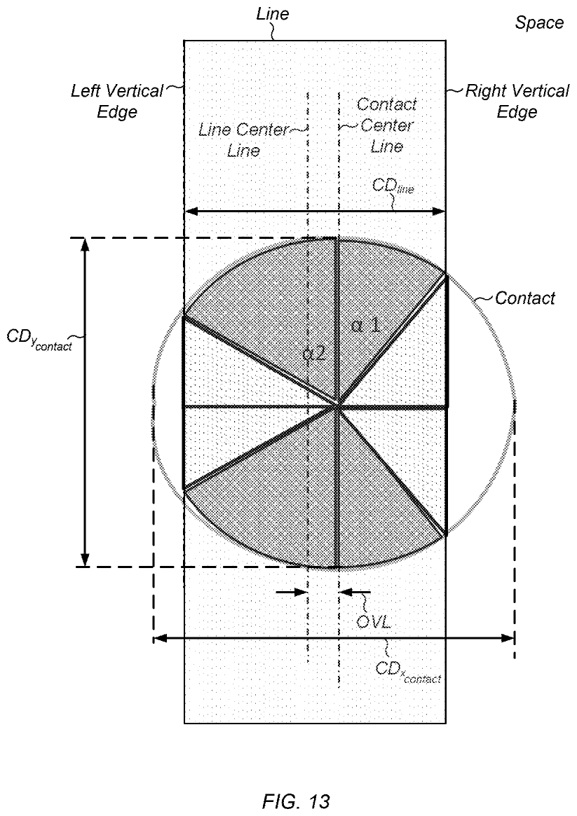

An alternative to using the integral solution of Equation 26, a geometric solution as depicted in FIG. 13, may be employed. The area of the ellipse over the line can be broken down into 4 sectors and 4 triangles. The sum of the sector areas Aₛ can be determined using Equation 27, and the sum of the area of the triangles Aₜ can be determined using Equation 28.

$${A}_{s} = ( {α}_{1} + {α}_{2} ) {r}^{2} \qquad ( 27 )$$

$${A}_{t} = ( cos ( {α}_{1} ) sin ( {α}_{1} ) + cos ( {α}_{2} ) sin ( {α}_{2} ) ) {r}^{2} \qquad ( 28 )$$

The area of the elliptical contact A can be determined using Equation 29, and the normalized area

$$\frac{{A}^{′}}{A}$$

is given by Equation 30.

$$A = π {r}^{2} \qquad ( 29 )$$

$$\frac{{A}^{′}}{A} = \frac{{A}_{s} + {A}_{t}}{A} = \frac{{α}_{1} + {α}_{2} + cos ( {α}_{1} ) sin ( {α}_{1} ) + cos ( {α}_{2} ) sin ( {α}_{2} )}{π} \qquad ( 30 )$$

It is noted that the above expressions are correct for both circular and elliptical contacts. In various embodiments, the cosine terms in the above equations can be expressed in terms of the geometric and metrology parameters as shown in Equations 31 and 32.

$$cos ( {α}_{1} ) = \frac{C {D}_{l i n e} - \frac{OVL}{2}}{C {D}_{{x}_{contact}}} \qquad ( 31 )$$

$$cos ( {α}_{2} ) = \frac{C {D}_{l i n e} + \frac{OVL}{2}}{C {D}_{{x}_{contact}}} \qquad ( 32 )$$

In contrast to previously described failure criteria, in the case of the elliptical contact, the failure criteria are not linear functions of the geometric metrology parameters CDₓ_{_{contact}}, CD_{y}_{_{contact}}, CDₗᵢₙₑ, and OVL, which precludes the option of developing a simple expression for the variance of A′, similar to that depicted in Equation 2.

In some embodiments, a stochastic simulation may be performed to evaluate the failure condition. For example, Equations 25, 28, and 30 can be employed to calculate a collection of results for the failure criterion

$$\frac{{A}^{′}}{A} ,$$

in which each of the metrology parameters is allowed to vary randomly according to a normal distribution using geometric and stochastic parameters, such as depicted in Table 2. The collection of results for

$$\frac{{A}^{′}}{A}$$

may then be statistically characterized.

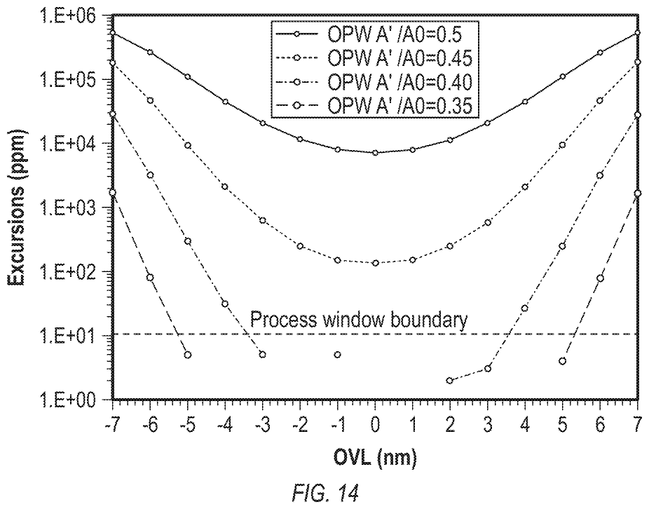

In the description above, A may represent the nominal contact area or the specific contact area. The results of a stochastic simulation are shown in FIG. 14 for four different failure criteria and in which A0 is a nominal contact area. As opposed to the cases analyzed above where the process window curves are calculated analytically, in this case, each data point is determined by counting excursions from one million independent stochastic simulations, resulting in random noise in the data which is observable for cases with less than 10 excursions. More interestingly, the process windows display a qualitatively different shape in that the curves are flatter and vary less steeply with overlay. This is the result of the more gradual dependence on the elliptical contact overlap with the line versus the threshold-like failure behavior of the previous examples. It is noted, however, that the dependence of the width of the overlay process window on the required contact area

$$\frac{{A}^{′}}{A}$$

is abrupt, going from entirely closed at

$$\frac{{A}^{′}}{A} = 0.45$$

to a width of ~7 nm at

$$\frac{{A}^{′}}{A} = 0.5$$

for the nominal criterion of 10 failures per million.

In other embodiments, the failure criterion

$$\frac{{A}^{′}}{A}$$

may be approximated by a parametric expression of the geometric and metrology parameters (e.g., CDₓ_{_{contact}}, CD_{y}_{_{contact}}, CDₓ_{ₗᵢₙₑ}, and OVL) and their respective variances.

As the above embodiments illustrate, this method can be applied to each of the patterning layers used in the manufacture of a semiconductor device. Geometric considerations lead to a calculation of a specific dimension or edge placement involving critical dimensions and pattern placements from at least two different patterning steps combined with the overlay between the patterns. A variance of the calculated dimension can also be determined based on the variance of the individual terms of the calculated dimension. The mean and variance of the calculated dimension leads to a prediction, based on the statistical distribution of the dimension, of the frequency of occurrence of a failure criterion for that dimension.

One method to analytically estimate the variance of the device failure criterion, which by way of example, could be

$${η}_{f} = \frac{A}{{A}_{0}} ,$$

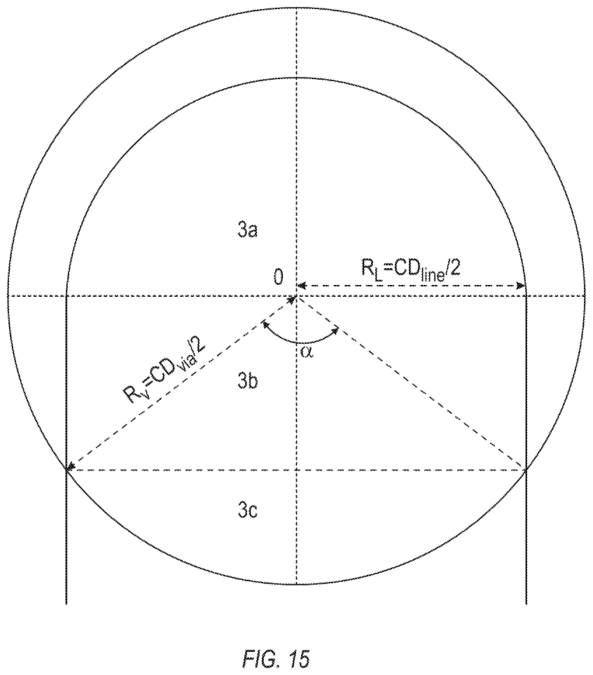

is by analytical error propagation. Propagation of error may be defined as the effects on a function by a variable's uncertainty. It is a calculus derived statistical calculation designed to combine uncertainties from multiple variables to provide an estimate of uncertainty of a composite function. This method will be illustrated for the case of a device geometry of a line-end over a via as shown in FIG. 15.

The area of this region is calculated geometrically as a sum of a contact line-end (a semicircle), denoted by 3a, a rectangle of width CDₗᵢₙₑ and height

$${R}_{v} * cos \frac{α}{2} + Y$$

denoted by 3b and a via minor segment of angle α, denoted by 3c, as depicted in Equation 33, where

$$sin \frac{α}{2} = \frac{{R}_{L}}{{R}_{v}} .$$

$$A = \frac{π}{2} {R}_{L}^{2} + 2 {R}_{L} * ( {R}_{v} * cos \frac{α}{2} + Y ) + \frac{1}{2} {R}_{v}^{2} [ α - sin α ] \qquad ( 33 )$$

It is noted that this is a complex function of the line and via CDs, but a linear function of overlay Y. This asymmetric function results in device failure only in the negative overlay Y direction. Note also that the slope of A versus Y in region 3 is simply 2R_{L}, the CD of the line.

An estimate of the variance

$${σ}_{A}^{2}$$

in A (as defined in Equation 33) resulting from variances in the metrology parameters, R_{L}, Rᵥ, and Overlay Y, is depicted in Equation 34, where x=R_{L}, y=Overlay Y, and z=Rᵥ.

$${σ}_{A}^{2} = {( \frac{\partial A}{\partial x} )}^{2} * {σ}_{x}^{2} + {( \frac{\partial A}{\partial y} )}^{2} * {σ}_{y}^{2} + {( \frac{\partial A}{\partial z} )}^{2} * {σ}_{z}^{2} \qquad ( 34 )$$

Substituting R_{L}=x, Overlay Y=y, and Rᵥ=z into Equation 33, a new expression for is depicted in Equation 35.

$$A = \frac{π}{2} {x}^{2} + 2 zx \sqrt{1 - {( \frac{x}{z} )}^{2}} + 2 xy + {z}^{2} {sin}^{- 1} \frac{x}{z} - zx \sqrt{1 - {( \frac{x}{z} )}^{2}} \qquad ( 35 )$$

A simplified version of Equation 35 is depicted in Equation 36.

$$A = \frac{π}{2} {x}^{2} + x \sqrt{{z}^{2} - {x}^{2}} + 2 x y + {z}^{2} {sin}^{- 1} \frac{x}{z} \qquad ( 36 )$$

Taking partial derivatives of Equation 36 yields expressions for as depicted in Equations 37, 38, and 39, respectively.

$$\frac{\partial A}{\partial x} = π x + 2 \sqrt{{z}^{2} - {x}^{2}} + 2 y \qquad ( 37 )$$

$$\frac{\partial A}{\partial y} = 2 x \qquad ( 38 )$$

$$\frac{\partial A}{\partial z} = 2 z {sin}^{- 1} \frac{x}{z} \qquad ( 39 )$$

Equations 37, 38, and 39 can be combined with Equation 34 to determine an analytical expression for the variance of A as show in Equation 40.

$${σ}_{A}^{2} = {( π x + 2 \sqrt{{z}^{2} - {x}^{2}} + 2 y )}^{2} * {σ}_{x}^{2} + 4 {x}^{2} * {σ}_{y}^{2} + {( 2 z {sin}^{- 1} \frac{x}{z} )}^{2} * {σ}_{z}^{2} \qquad ( 40 )$$

Equation 40 provides an estimate for the variance of the feature overlap area as a function of the metrology parameters and their variances. A cumulative Gaussian distribution function Φ can be employed, as shown in Equation 41 to estimate the proportion of failures, where μ_{A} is calculated using Equation 36,

$${A}_{0} = π {R}_{v}^{2} ,$$

and η_{f}, as above, is interpreted as the area threshold parameter for failure.

$$Φ ( {η}_{f} * {A}_{0 ,} {μ}_{A ,} {σ}_{A} ) = \frac{1}{\sqrt{2 π} {σ}_{A}} {\int }_{- ∞}^{{η}_{f} * {A}_{0}} {e}^{- \frac{{( A - {μ}_{A} )}^{2}}{2 {σ}_{A}^{2}}} dA \qquad ( 41 )$$

Example curves for the failure rate as a function of Overlay Y for different ratios of

$$\frac{{R}_{L}}{{R}_{v}}$$

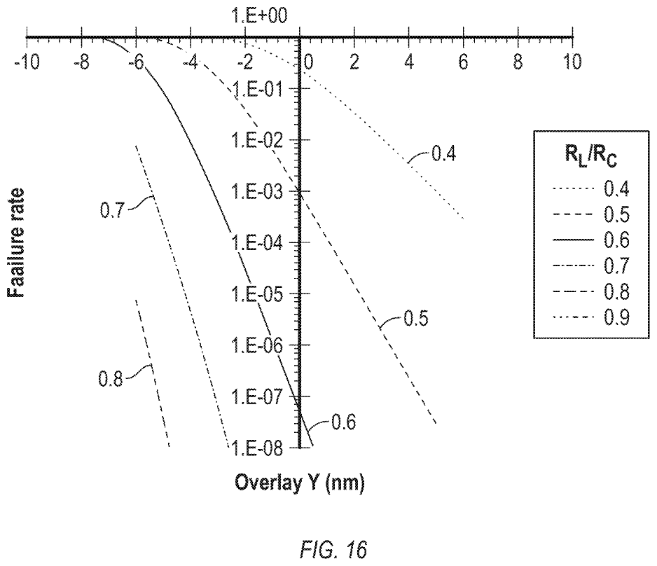

and for n_{f}=0.3 are depicted in FIG. 16.

In a further embodiment of the above method, the parameter n_{f} may be estimated by fitting the analytically predicted failure rate to experimentally determined failure rates on a test wafer. One method for performing such calibration is by use of voltage contrast measurements.

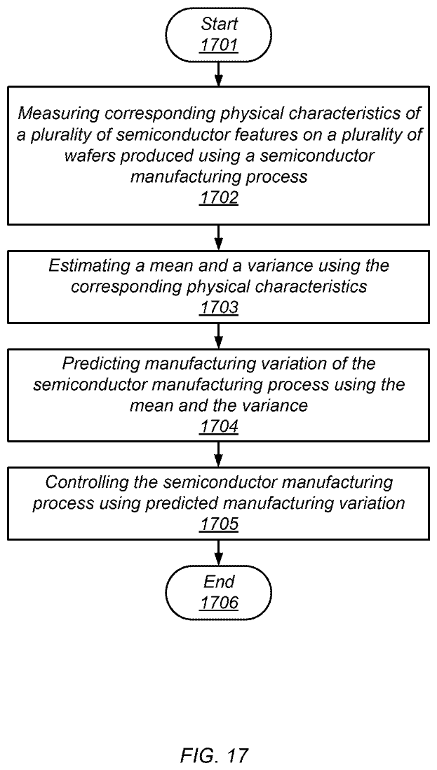

Turning to FIG. 17, a flow diagram depicting an embodiment of a method for controlling a semiconductor manufacturing process is illustrated. The method, which may be applied to various semiconductor manufacturing processes, begins in block 1701.

The method includes measuring corresponding physical characteristics of a plurality of semiconductor features on a plurality of wafers produced using a semiconductor manufacturing process (block 1702). In some embodiments, the corresponding physical characteristics include corresponding dimensions of the plurality of semiconductor features and corresponding positions of the plurality of semiconductor features.

The method further includes estimating a mean and a variance using the corresponding physical characteristics (block 1703). In some embodiments, estimating the mean and the variance includes combining data from multiple dies on a common wafer. In other embodiments, estimating the mean and the variance includes combining data from multiple dies across multiple wafers.

The method also includes predicting manufacturing variation of the semiconductor manufacturing process using the mean and the variance (block 1704). In some embodiments, predicting the manufacturing variation of the semiconductor manufacturing process using the mean and the variance includes combining the mean and the variance. In various embodiments, combining the mean and the variance includes generating a quotient of the mean and the variance. In such cases, predicting the manufacturing variation may include generating a prediction using an error function and the quotient of the mean and the variance.

The method further includes controlling the semiconductor manufacturing process using predicted manufacturing variation (block 1705). In various embodiments, controlling the semiconductor manufacturing process may include adjusting a lithography tool used in the semiconductor manufacturing process. In other embodiments, controlling the semiconductor manufacturing process may include adjusting an etch tool used in the semiconductor manufacturing process.

The method concludes in block 1706. It is noted that the embodiment of the method depicted in FIG. 17 may be implemented by one or more processors or processor cores executing program instructions stored in a tangible non-transitory computer-readable storage medium such as a hard-disk drive, a non-volatile memory circuit, and the like.

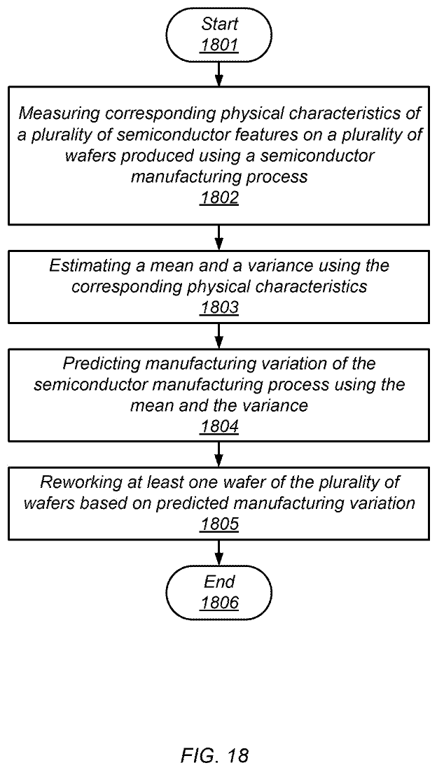

Turning to FIG. 18, a flow diagram depicting an embodiment of a method for reworking wafers produced by a semiconductor manufacturing process is illustrated. The method, which may be applied to various semiconductor manufacturing processes, begins in block 1801.

The method includes measuring corresponding physical characteristics of a plurality of semiconductor features on a plurality of wafers produced using a semiconductor manufacturing process (block 1802).

The method further includes estimating a mean and a variance using the corresponding physical characteristics (block 1803). In some embodiments, estimating the mean and the variance includes combining data from multiple dies on a common wafer. In other embodiments, estimating the mean and the variance includes combining data from multiple dies across multiple wafers.

The method also includes predicting manufacturing variation of the semiconductor manufacturing process using the mean and the variance (block 1804). In some embodiments, predicting the manufacturing variation of the semiconductor manufacturing process using the mean and the variance includes combining the mean and the variance. In various embodiments, combining the mean and the variance includes generating a quotient of the mean and the variance. In such cases, predicting the manufacturing variation may include generating a prediction using an error function and the quotient of the mean and the variance

The method further includes reworking at least one wafer of the plurality of wafers based on predicted manufacturing variation (block 1805). In various embodiments, reworking the at least one wafer of the plurality of wafers includes removing a previously deposited material, and then repeating deposition and lithographic operations associated with the material. In another embodiment, if reworking the wafer or wafers is not possible, the wafer or wafers may be scrapped instead.

The method concludes in block 1806. It is noted that the embodiment of the method depicted in FIG. 16 may be implemented by one or more processors or processor cores executing program instructions stored in a tangible non-transitory computer-readable storage medium such as a hard-disk drive, a non-volatile memory circuit, and the like.

The embodiments described in the present disclosure assume a specific design of the patterns involved, including designed values for various dimensions. Changing these designed values will change the actual patterns generated on the wafer, and also the control of the semiconductor manufacturing process as described in this disclosure. Some designs might result in effective control of the semiconductor manufacturing process and high manufacturing yield. For example, a design with larger feature dimensions might results in a larger overlay process window, better manufacturing control, and higher yield. However, these larger designed dimensions might increase the total area of the chip, reduce the number of chips that can be manufactured on one wafer, and increase the manufacturing cost per chip. Thus, there could be a trade-off between the chip area and number of chips per wafer, and the chip yield. Other design trade-offs affecting cost per die are also possible.

The various embodiments in the present disclosure can include the step of optimizing the trade-off between chip cost and chip yield as a function of chip design parameters, such as the designed dimensions of various structures to be patterned on the wafer. These trade-offs can be used to reduce the cost per good die manufactured.

The present disclosure includes references to “an embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

“A”, “an”, and “the”, as used herein, refers to both singular and plural referents unless the context clearly dictates otherwise. By way of example, “a processor” programmed to perform various functions refers to one processor programmed to perform each and every function, or more than one processor collectively programmed to perform each of the various functions.

Numerous variations and modifications will become apparent to those skilled in the art once the above disclosure is fully appreciated. It is intended that the following claims be interpreted to embrace all such variations and modifications.

1-20. (canceled)

21. A method, comprising:
measuring corresponding physical characteristics of a plurality of semiconductor features on a plurality of wafers produced using a semiconductor manufacturing process;
estimating, using the corresponding physical characteristics, at least one local variation metric associated with the semiconductor features;
generating, based on the at least one local variation metric, an output representing:
(i) a segment unbiased local critical dimension uniformity (segment unbiased LCDU),
(ii) a segment unbiased local pattern placement error (segment unbiased LPPE), the output characterizing local stochastic variation of at least one of feature dimensions or feature positions, or
(iii) some combination thereof; and
controlling the semiconductor manufacturing process using the output representing the at least one of the segment unbiased LCDU or the segment unbiased LPPE.

22. The method of claim 21, further comprising:
combining the segment unbiased LCDU and the segment unbiased LPPE to estimate an edge placement error; and
generating, using the edge placement error, a prediction of a probability of device failure.

23. The method of claim 21, further comprising jointly analyzing the segment unbiased LCDU and segment unbiased LPPE to characterize stochastic process variation.

24. The method of claim 21, wherein generating the segment unbiased LCDU comprises removing measurement bias from a local dimensional variation metric.

25. The method of claim 21, wherein generating the segment unbiased LPPE comprises compensating for systematic placement errors.

26. The method of claim 21, further comprising characterizing, using the segment unbiased LCDU, a stochastic dimensional variation, wherein characterizing the stochastic dimensional variation comprises excluding a global critical dimension variation.

27. The method of claim 21, further comprising characterizing, using the segment unbiased LPPE, a stochastic placement variation, wherein characterizing the stochastic placement variation comprises excluding global pattern placement error.

28. The method of claim 21, wherein the segment unbiased LCDU is associated with a defined local segment of a semiconductor feature, the segment having a length equal to an overall length of the semiconductor feature.

29. The method of claim 21, wherein the segment unbiased LPPE represents local placement variation over a region of a feature interaction.

30. The method of claim 21, wherein controlling the semiconductor manufacturing process includes adjusting a lithography tool used in the semiconductor manufacturing process.

31. An apparatus, comprising:
a measurement device configured to measure corresponding physical characteristics of a plurality of semiconductor features on a plurality of wafers produced using a semiconductor manufacturing process to generate measurement data; and
an information system configured to:
estimate, using the measurement data, at least one local variation metric associated with the semiconductor features;
generate, based on the at least one local variation metric, an output representing:
(i) a segment unbiased local critical dimension uniformity (segment unbiased LCDU),
(ii) a segment unbiased local pattern placement error (segment unbiased LPPE), or
(iii) some combination thereof; and
control the semiconductor manufacturing process using the output representing the at least one of the segment unbiased LCDU or the segment unbiased LPPE.

32. The apparatus of claim 31, wherein the information system is further configured to:
combine the segment unbiased LCDU and the segment unbiased LPPE to estimate an edge placement error; and
generate, using the edge placement error, a prediction of a probability of device failure.

33. The apparatus of claim 31, wherein the information system is further configured to jointly analyze the segment unbiased LCDU and segment unbiased LPPE to characterize stochastic process variation.

34. The apparatus of claim 31, wherein to generate the segment unbiased LCDU, the information system is configured to remove measurement bias from a local dimensional variation metric.

35. The apparatus of claim 31, wherein to generate the segment unbiased LPPE, the information system is configured to compensate for systematic placement errors.

36. The apparatus of claim 31, wherein the information system is further configured to characterize, using the segment unbiased LCDU, a stochastic dimensional variation, wherein to characterize the stochastic dimensional variation, the information system is configured to exclude a global critical dimension variation.

37. The apparatus of claim 31, wherein the information system is further configured to characterize, using the segment unbiased LPPE, a stochastic placement variation, wherein to characterize the stochastic placement variation, the information system is configured to excluding global pattern placement error.

38. The apparatus of claim 31, wherein the segment unbiased LCDU is associated with a defined local segment of a semiconductor feature, the segment having a length equal to an overall length of the semiconductor feature, and wherein the segment unbiased LPPE represents local placement variation over a region of a feature interaction.

39. The apparatus of claim 31, wherein to control the semiconductor manufacturing process using the output, the information system is configured to generate control signals to adjust a lithography tool used in the semiconductor manufacturing process.

40. A non-transitory computer-readable medium having program instructions stored therein that, in response to execution by a computer system, causes the computer system to perform operations comprising:
measuring corresponding physical characteristics of a plurality of semiconductor features on a plurality of wafers produced using a semiconductor manufacturing process;
estimating, using the corresponding physical characteristics, at least one local variation metric associated with the semiconductor features;
generating, based on the at least one local variation metric, an output representing:
(i) a segment unbiased local critical dimension uniformity (segment unbiased LCDU),
(ii) a segment unbiased local pattern placement error (segment unbiased LPPE), the output characterizing local stochastic variation of at least one of feature dimensions or feature positions, or
(iii) some combination thereof; and
controlling the semiconductor manufacturing process using the output representing the at least one of the segment unbiased LCDU or the segment unbiased LPPE.
